(19) United States
(12) Patent Application Publication
(10) Pub. No.: US 2025/0015202 A1
(43) Pub. Date: Jan. 9, 2025

(54) SEMICONDUCTOR DEVICE

(71) Applicant: ROHM CO., LTD., Kyoto (JP)

(72) Inventor: Mitsuhide KORI, Kyoto (JP)

(73) Assignee: ROHM CO., LTD., Kyoto (JP)

(21) Appl. No.: 18/895,017

(22) Filed: Sep. 24, 2024

Related U.S. Application Data
(63) Continuation of application No. PCT/JP2023/004641, filed on Feb. 10, 2023.

(30) Foreign Application Priority Data
Mar. 30, 2022 (JP) 2022-055515

(51) Int. Cl. H01L 29/872; H01L 29/49; H01L 29/66

(52) U.S. Cl. CPC H01L 29/872; H01L 29/495; H01L 29/4975; H01L 29/66143

(57) ABSTRACT

A semiconductor device includes a chip having a principal surface, a pn-junction portion extending in a horizontal direction along the principal surface inside the chip, a trench insulating structure formed in the principal surface such that the trench insulating structure penetrates through the pn-junction portion, and demarcating a diode region in the chip, a barrier forming region formed in a surface layer portion of the principal surface in the diode region, and a metal layer located on the principal surface such that the metal layer covers the barrier forming region in the diode region, and forming a Schottky-junction portion with the barrier forming region.

### CROSS REFERENCE TO RELATED APPLICATIONS

The present application is a bypass continuation application of International Patent Application No. PCT/JP2023/004641, filed on Feb. 10, 2023, which corresponds to Japanese Patent Application No. 2022-055515 filed on Mar. 30, 2022 with the Japan Patent Office, and the entire disclosure of this application is incorporated herein by reference.

### TECHNICAL FIELD

The present disclosure relates to a semiconductor device.

### BACKGROUND ART

Patent Document 1 (Japanese Unexamined Patent Application Publication No. 2015-122543) discloses a semiconductor device including a p-type region, a first p-type epitaxial region, an n-type embedded region, a second p-type epitaxial region, and a Deep Trench Isolation (DTI) structure. The first p-type epitaxial region is formed on the p-type region. The n-type embedded region is formed on the first p-type epitaxial region. The second p-type epitaxial region is formed on the n-type embedded region. The DTI structure surrounds the formation region of a high withstand voltage lateral MOS transistor in a plan view. The DTI structure penetrates through the second p-type epitaxial region, the n-type embedded region, and the first p-type epitaxial region such as to reach the p-type region.

### BRIEF DESCRIPTION OF DRAWINGS

FIG. 1 is a schematic perspective view of a semiconductor device according to a preferred embodiment of the present disclosure.

FIG. 2 is an enlarged plan view of a diode region in FIG. 1.

FIG. 3 is a sectional view taken along line III-III illustrated in FIG. 2.

FIGS. 4A to 4L are views each illustrating a part of a manufacturing process of a Schottky barrier diode in FIG. 3.

### DESCRIPTION OF EMBODIMENTS

Next, a preferred embodiment of the present disclosure will be described in detail with reference to the accompanying drawings.

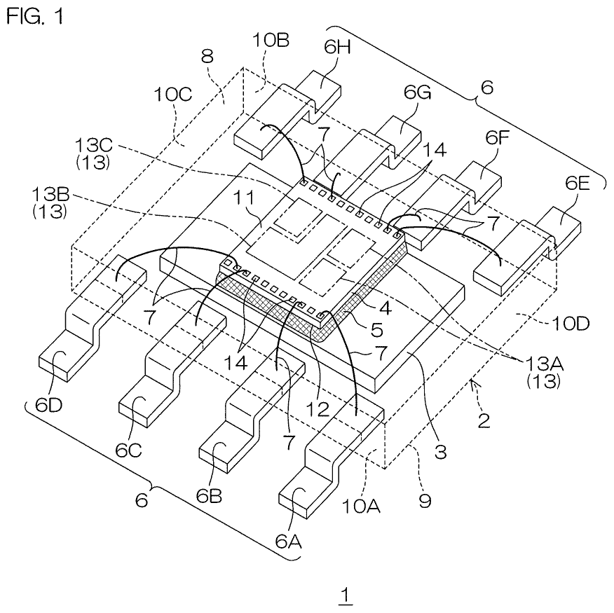

FIG. 1 is a schematic perspective view of a semiconductor device 1 according to a preferred embodiment of the present disclosure.

The semiconductor device 1 is, in this preferred embodiment, a so-called SOP (Small Outline Package). The semiconductor device 1 includes a sealing resin 2, a die pad 3, a semiconductor chip 4, a conductive bonding material 5, a plurality of lead terminals 6, and a plurality of lead wires 7.

The sealing resin 2 may include, for example, epoxy resin. The sealing resin 2 may be restated as a resin package. The sealing resin 2 is formed into a rectangular parallelepiped shape. The sealing resin 2 includes a first principal surface 8 on one side, a second principal surface 9 on the other side, and four side surfaces 10A, 10B, 10C, and 10D connecting the first principal surface 8 and the second principal surface 9. Specifically, the four side surfaces 10A to 10D include a first side surface 10A, a second side surface 10B, a third side surface 10C, and a fourth side surface 10D. The first side surface 10A and the second side surface 10B are opposite to each other. The third side surface 10C and the fourth side surface 10D are opposite to each other.

The die pad 3 is located inside the sealing resin 2. The die pad 3 may be exposed from the second principal surface 9. The die pad 3 includes a metal plate formed into a rectangular parallelepiped shape. The die pad 3 may include at least one of Fe, Au, Ag, Cu, and Al. The die pad 3 may have an outer surface on which at least one of the Ni-, Au-, Ag-, and Cu-plated layers is formed.

The plurality of lead terminals 6 include a first lead terminal 6A, a second lead terminal 6B, a third lead terminal 6C, a fourth lead terminal 6D, a fifth lead terminal 6E, a sixth lead terminal 6F, a seventh lead terminal 6G, and an eighth lead terminal 6H. The number of lead terminals 6 is adjusted according to the functions of the semiconductor chip 4, and is not limited to the number illustrated in FIG. 1.

The four lead terminals 6A to 6D are located at the first side surface 10A side of the sealing resin 2. The four lead terminals 6A to 6D are spaced from the die pad 3. The four lead terminals 6A to 6D are aligned at intervals in an extending direction of the first side surface 10A. The four lead terminals 6A to 6D are drawn out from the inside of the sealing resin 2 to the outside of the sealing resin 2 across the first side surface 10A.

The four lead terminals 6E to 6H are located at the second side surface 10B side of the sealing resin 2. The four lead terminals 6E to 6H are spaced from the die pad 3. The four lead terminals 6E to 6H are aligned at intervals in an extending direction of the second side surface 10B. The four lead terminals 6E to 6H are drawn out from the inside of the sealing resin 2 to the outside of the sealing resin 2 across the second side surface 10B.

The plurality of lead terminals 6 may include at least one of Fe, Au, Ag, Cu, and Al. The plurality of lead terminals 6 may have an outer surface on which at least one of the Ni-, Au-, Ag-, and Cu-plated layers is formed.

The semiconductor chip 4 includes, for example, an LSI (Large-Scale Integration) chip. The semiconductor chip 4 is located on the die pad 3. The semiconductor chip 4 has a first principal surface 11 on one side and a second principal surface 12 on the other side. On the first principal surface 11 of the semiconductor chip 4, a plurality of element regions 13 in which elements constituting a circuit of the LSI are fabricated are formed. The plurality of element regions 13 may include, for example, a diode region 13A, a transistor region 13B, and a resistor element region 13C, etc. On the first principal surface 11 of the semiconductor chip 4, a plurality of pads 14 are formed. The plurality of pads 14 are aligned at the side of the four lead terminals 6A to 6D and the side of the four lead terminals 6E to 6H on the first principal surface 11 of the semiconductor chip 4. The plurality of pads 14 are electrically connected to various functional elements (circuit elements constituting the LSI) formed in the element regions 13.

The conductive bonding material 5 is interposed between the semiconductor chip 4 and the die pad 3, and bonds the semiconductor chip 4 to the die pad 3. The conductive bonding material 5 includes a solder or conductive paste. The solder may be a lead-free solder. The solder may include at least one of SnAgCu, SnZnBi, SnCu, SnCuNi, and SnSbNi. The metal paste may include at least one of Au, Ag, and Cu. The conductive bonding material 5 is preferably made of a silver paste. The silver paste particularly preferably includes a sintered silver paste. The sintered silver paste may include a paste obtained by dispersing nanosized or microsized Ag particles into an organic solvent.

The plurality of lead wires 7 are adjusted according to the functions of the semiconductor chip 4, and the number of lead wires is not limited to the number illustrated in FIG. 1. The plurality of lead wires 7 electrically connect the plurality of lead terminals 6 and the plurality of pads 14. The plurality of lead wires 7 include, in the present preferred embodiment, aluminum wires as an example of bonding wires. The plurality of lead wires 7 may be gold wires or copper wires in place of aluminum wires.

The package form of the semiconductor device 1 may be a form other than an SOP. For example, the semiconductor device 1 may have a package form of a TO (Transistor Outline), a QFN (Quad For Non lead package), a DFP (Dual Flat Package), DIP (Dual Inline Package), a QFP (Quad Flat Package), an SIP (Single Inline Package), or an SOJ (Small Outline J-leaded Package) or various package forms analogous to these forms.

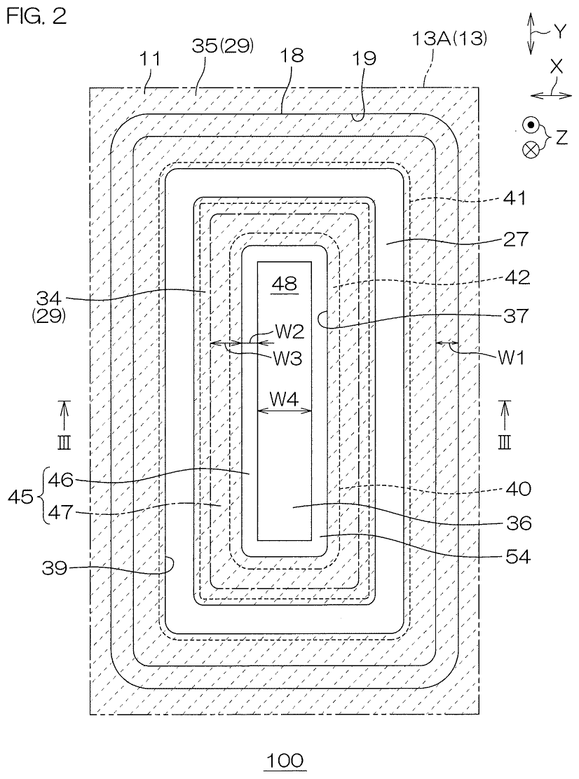

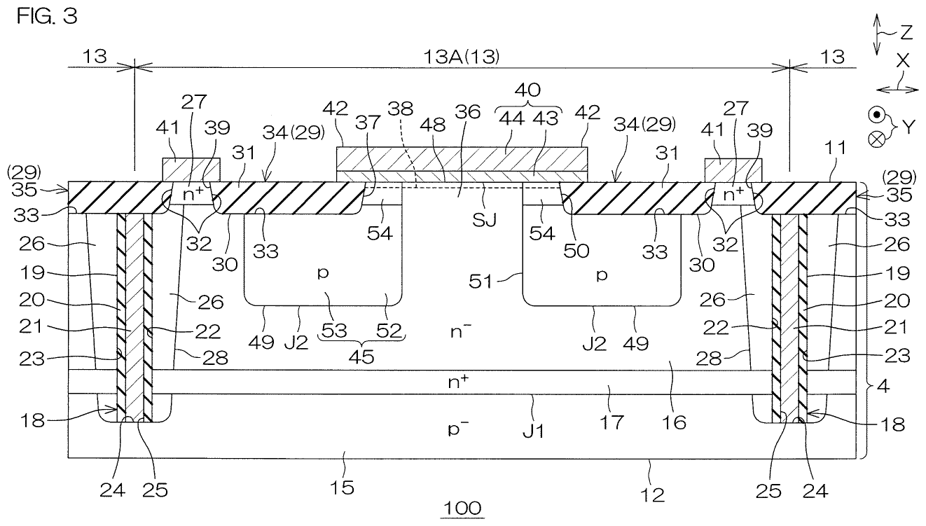

FIG. 2 is an enlarged plan view of the diode region 13A illustrated in FIG. 1. FIG. 3 is a sectional view taken along line III-III illustrated in FIG. 2. In FIG. 2, for clarification, a shallow trench insulating structure 29 is hatched.

The diode region 13A is, in the present preferred embodiment, a region in which a Schottky barrier diode 100 is formed. The Schottky barrier diode 100 may be controlled by, for example, a switching element (for example, MOSFET or the like) formed in the transistor region 13B.

The semiconductor chip 4 includes a first layer 15 of p-type, a second layer 16 of p-type or n-type, and a third layer 17 of n-type. The first layer 15 may be referred to as a “base layer.” The second layer 16 may be referred to as a “device forming layer.” The third layer 17 may be referred to as an “embedded layer.” The first layer 15, the second layer 16, and the third layer 17 may be regarded as components of the semiconductor chip 4.

The first layer 15 is formed in a region on the second principal surface 12 side in the semiconductor chip 4, and forms the second principal surface 12. In the first layer 15, a p-type impurity concentration at the first principal surface 11 side may have a lower concentration gradient than a p-type impurity concentration at the second principal surface 12 side. Specifically, the first layer 15 may have a laminated structure including a high-concentration layer and a low-concentration layer laminated in this order from the second principal surface 12 side. The first layer 15 may have a thickness of, for example, 100 μm or more and 600 μm or less. The first layer 15 may be formed by a p-type semiconductor substrate (Si substrate) in the present preferred embodiment.

The second layer 16 is formed in a region on the first principal surface 11 side in the semiconductor chip 4, and forms the first principal surface 11. The conductivity type (n-type or p-type) of the second layer 16 is optional, and is selected according to the specifications of the semiconductor device 1. In the present preferred embodiment, an example in which the conductivity type of the second layer 16 is the n-type will be described, but this does not intend to limit the conductivity type of the second layer 16 to the n-type. The second layer 16 may have an n-type impurity concentration uniform in a thickness direction, or may have an n-type impurity concentration gradient that rises toward the first principal surface 11. The second layer 16 may be formed by an n-type epitaxial layer (Si epitaxial layer) in the present preferred embodiment.

The third layer 17 is interposed in a region between the first layer 15 and the second layer 16 in the semiconductor chip 4. The third layer 17 forms a pn-junction portion J1 at the boundary portion with the first layer 15. In other words, in the semiconductor chip 4, a pn-junction portion J1 extending in a horizontal direction (direction orthogonal to the thickness direction) along the first principal surface 11 is formed at the halfway portion in the thickness direction between the first principal surface 11 and the second principal surface 12. The pn-junction portion J1 may be referred to as a “pn-connection portion,” or a “pn-boundary portion.”

The third layer 17 has an n-type impurity concentration that is higher than that of the second layer 16. Specifically, in the third layer 17, an n-type impurity concentration at the first principal surface 11 side may have a higher concentration gradient than an n-type impurity concentration at the second principal surface 12 side. The third layer 17 may have a thickness of, for example, 0.1 μm or more and 10 μm or less. The third layer 17 may be formed by an n-type epitaxial layer (Si epitaxial layer) in the present preferred embodiment.

The semiconductor device 1 includes a trench insulating structure 18 that demarcates the diode region 13A in the first principal surface 11. The trench insulating structure 18 demarcates the diode region 13A with a predetermined shape in a plan view. The trench insulating structure 18 electrically isolates the diode region 13A from other element regions 13. Therefore, the trench insulating structure 18 may be referred to as an “element isolation structure.”

Referring to FIG. 2, the trench insulating structure 18 is formed into a belt shape extending along the diode region 13A in a plan view. In the present preferred embodiment, the trench insulating structure 18 is formed into an annular shape (quadrangular annular shape in the present preferred embodiment) in a plan view, and demarcates the diode region 13A with a predetermined shape (quadrilateral shape in the present preferred embodiment). The four corners of the trench insulating structure 18 have round shapes curved in directions away from the diode region 13A in a plan view in the present preferred embodiment. A planar shape of the trench insulating structure 18 (a planar shape of the diode region 13A) is optional. The trench insulating structure 18 may be formed into a polygonal annular shape, a circular annular shape, or an oval annular shape in a plan view, and may demarcate the diode region 13A with a polygonal, circular, or oval shape in a plan view.

Referring to FIG. 2, the trench insulating structure 18 has a trench width W1. The trench width W1 is the width in the direction orthogonal to the extending direction of the trench insulating structure 18 in a plan view. The trench width W1 may be 0.5 μm or more and 10 μm or less.

Referring to FIG. 3, the trench insulating structure 18 is formed in the first principal surface 11 such as to penetrate through the pn-junction portion J1, and demarcates the diode region 13A in the first principal surface 11. Specifically, the trench insulating structure 18 penetrates through the second layer 16 and the third layer 17 such as to reach the first layer 15, and demarcates the diode region 13A in the second layer 16. The trench insulating structure 18 extends from the first principal surface 11 to the second principal surface 12 side such as to reach the first layer 15, and penetrates through the second layer 16 and the third layer 17 in the present preferred embodiment.

The trench insulating structure 18 includes an inner peripheral wall at the diode region 13A side, an outer peripheral wall at the opposite side of the inner peripheral wall (peripheral edge side of the semiconductor chip 4), and a bottom wall connecting the inner peripheral wall and the outer peripheral wall. The trench insulating structure 18 is electrically connected to the semiconductor chip 4 at the bottom wall and electrically insulated from the semiconductor chip 4 at the side walls (inner and outer peripheral walls). That is, the trench insulating structure 18 has a lower end portion electrically connected to the semiconductor chip 4. Specifically, the trench insulating structure 18 is electrically connected to the first layer 15 and electrically insulated from the second layer 16 and the third layer 17. That is, the trench insulating structure 18 is fixed at the same potential as the first layer 15.

The trench insulating structure 18 includes an element isolation trench 19, an element isolation insulating film 20, and an element isolation electrode 21.

Referring to FIG. 2, the element isolation trench 19 is formed into an annular shape in a plan view. The width of the element isolation trench 19 may be the trench width W1 described above. Referring to FIG. 3, the element isolation trench 19 is formed at the first principal surface 11 side of the semiconductor chip 4 such as to penetrate through the pn-junction portion J1. Specifically, the element isolation trench 19 penetrates through the second layer 16 and the third layer 17 such as to reach the first layer 15. The element isolation trench 19 includes an inner peripheral wall 22 on the diode region 13A side, an outer peripheral wall 23 on the opposite side of the inner peripheral wall 22 (the peripheral edge side of the semiconductor chip 4), and a bottom wall 24 connecting the inner peripheral wall 22 and the outer peripheral wall 23. The inner peripheral wall 22 and the outer peripheral wall 23 may be referred to as an “inner wall” and an “outer wall,” or as a “first side wall” and a “second side wall,” respectively.

The element isolation insulating film 20 covers the inner peripheral wall 22 and the outer peripheral wall 23 of the element isolation trench 19 such as to expose the semiconductor chip 4 from the bottom wall 24 of the element isolation trench 19. Specifically, the element isolation insulating film 20 exposes the first layer 15 from the bottom wall 24 of the element isolation trench 19. The element isolation insulating film 20 preferably covers the entire region of the inner peripheral wall 22 and the entire region of the outer peripheral wall 23 of the element isolation trench 19. The region in which the bottom wall 24 of the element isolation trench 19 is exposed may be a contact hole 25 of the element isolation insulating film 20. The element isolation insulating film 20 may include a silicon oxide film. The element isolation insulating film 20 preferably includes a silicon oxide film made of an oxide of the semiconductor chip 4.

The element isolation electrode 21 is embedded in the element isolation trench 19 with the element isolation insulating film 20 in between and electrically connected to the semiconductor chip 4 at the bottom wall 24 of the element isolation trench 19. Specifically, the element isolation electrode 21 is electrically connected to the first layer 15 through the contact hole 25 and is electrically insulated from the second layer 16 and the third layer 17 by the element isolation insulating film 20. The element isolation electrode 21 preferably includes conductive polysilicon. The element isolation electrode 21 preferably includes conductive polysilicon with the same conductivity type (p-type in the present preferred embodiment) as the first layer 15. The p-type impurity of the element isolation electrode 21 is preferably boron. Wiring not illustrated may be connected to the element isolation electrode 21. Accordingly, the potential of the element isolation electrode 21 can be controlled through this wiring.

The semiconductor device 1 further includes a sinker layer 26 formed in the second layer 16. The sinker layer 26 extends across the pn-junction portion J1 in a depth direction of the element isolation trench 19, and is in contact with the first layer 15 and the element isolation insulating film 20. More specifically, the sinker layer 26 is formed into an annular shape along the inner peripheral wall 22 and the outer peripheral wall 23 of the element isolation trench 19, and is in contact with the element isolation insulating film 20 throughout the entirety of the element isolation trench 19 in the depth direction as illustrated in FIG. 3. The sinker layer 26 may have a thickness of 0.5 μm to 5 μm in a direction orthogonal to the depth direction of the element isolation trench 19.

A cathode region 27 is formed at the end portion on the first principal surface 11 side of the sinker layer 26 along the inner peripheral wall 22. The cathode region 27 is exposed from the first principal surface 11. The cathode region 27 is formed into an annular shape along the element isolation trench 19 as illustrated in FIG. 2. Referring to FIG. 3, the cathode region 27 may be across a boundary portion 28 between the sinker layer 26 and the second layer 16 adjacent to each other in a horizontal direction along the first principal surface 11. Accordingly, the cathode region 27 may stretch between the sinker layer 26 and the second layer 16 and may be connected to both of the sinker layer 26 and the second layer 16.

The sinker layer 26 has the same conductivity type as that of the third layer 17 and is an n-type in the present preferred embodiment. Similarly, the cathode region 27 also has the same conductivity type as that of the third layer 17 and the sinker layer 26 and is an n⁺ type in the present preferred embodiment. An impurity concentration of the cathode region 27 may be higher than that of the sinker layer 26.

A shallow trench insulating structure 29 is formed in a surface layer portion of the semiconductor chip 4. In the present preferred the embodiment, shallow trench insulating structure 29 includes a trench 30 formed in the second layer 16 and an embedded insulator 31 embedded in the trench 30.

The trench 30 has a side surface 32 and a bottom surface 33. The side surface 32 of the trench 30 may be a surface orthogonal to the first principal surface 11, or may be a surface tilting with respect to the first principal surface 11 as illustrated in FIG. 3. The trench 30 may have a tapered shape with a width narrowing from the first principal surface 11 toward the bottom surface 33 in a third direction Z when viewed in cross section.

The embedded insulator 31 may be, for example, silicon oxide (SiO₂), silicon nitride (SiN), or the like. The embedded insulator 31 is made of silicon oxide in the present preferred embodiment. The shallow trench insulating structure 29 may be commonly referred to as STI (Shallow Trench Isolation).

In the present preferred embodiment, the shallow trench insulating structure 29 may include a plurality of shallow trench insulating structures 29. The plurality of shallow trench insulating structures 29 may include a first shallow trench insulating structure 34 and a second shallow trench insulating structure 35 physically isolated from each other. A barrier forming region 36 is demarcated in an inner region of the first shallow trench insulating structure 34, and a cathode region 27 is demarcated between the first shallow trench insulating structure 34 and the second shallow trench insulating structure 35.

In the present preferred embodiment, the first shallow trench insulating structure 34 is formed into an annular shape in a plan view which has a first opening 37 (inner opening) that exposes the barrier forming region 36. The first shallow trench insulating structure 34 is formed into a long thin annular shape in a plan view, and the first opening 37 at a center portion of the first shallow trench insulating structure 34 is also similarly formed into a long thin and substantially rectangular shape. The barrier forming region 36 may be a portion of the semiconductor chip 4 (second layer 16) exposed from the first opening 37 demarcated by the inner peripheral edge of the first shallow trench insulating structure 34. The barrier forming region 36 may include a portion having the same n-type impurity concentration as that of the second layer 16.

A silicide layer 38 is formed in the barrier forming region 36. The silicide layer 38 is formed at an uppermost surface on the first principal surface 11 side of the semiconductor chip 4. The silicide layer 38 is exposed throughout the entire region of the first opening 37 in the present preferred embodiment. The silicide layer 38 includes at least one of, for example, the TiSi, TiSi₂, NiSi, CoSi, CoSi₂, MoSi₂, and WSi₂ layers. In the present preferred embodiment, the silicide layer 38 is composed of a CoSi₂ layer.

Referring to FIG. 2, the second shallow trench insulating structure 35 is spaced outward from the annular first shallow trench insulating structure 34 and surrounds the first shallow trench insulating structure 34 in a plan view. The second shallow trench insulating structure 35 is formed at a constant distance from the first shallow trench insulating structure 34. Accordingly, a second opening 39 (outer opening) that has a constant width along a circumferential direction and has a long thin and substantially quadrangular annular shape is formed between the first shallow trench insulating structure 34 and the second shallow trench insulating structure 35.

The cathode region 27 is exposed from the second opening 39 demarcated by an outer peripheral edge of the first shallow trench insulating structure 34 and an inner peripheral edge of the second shallow trench insulating structure 35. The cathode region 27 does not need to be formed throughout the entire region of the second opening 39 in the circumferential direction. In other words, a plurality of cathode regions 27 may be aligned at intervals along the circumferential direction of the second opening 39.

The second shallow trench insulating structure 35 stretches from one side to the other of the diode region 13A and the element region 13 at an outer side of the diode region 13A with respect to the trench insulating structure 18. That is, the second shallow trench insulating structure 35 overlaps both of the diode region 13A and another element region 13 in a plan view.

On the first principal surface 11 of the semiconductor chip 4, a first conductive layer 40 and a second conductive layer 41 are formed. The first conductive layer 40 may be rested as an anode conductive layer of the Schottky barrier diode 100, and the second conductive layer 41 may be rested as a cathode conductive layer of the Schottky barrier diode 100.

The first conductive layer 40 has a substantially rectangular shape long and thin along the shape of the first opening 37 in a plan view as illustrated in FIG. 2. Referring to FIGS. 2 and 3, the first conductive layer 40 covers the entire region of the first opening 37, and is in contact with the barrier forming region 36. In addition, the first conductive layer 40 has a drawn-out portion 42 drawn out from the upper surface of the barrier forming region 36 onto the first shallow trench insulating structure 34. The drawn-out portion 42 is formed annularly throughout the entirety of the first opening 37 in the circumferential direction. The first opening 37 is surrounded by the drawn-out portion 42.

The first conductive layer 40 includes a first layer 43 and a second layer 44 laminated in order from the first principal surface 11. The first layer 43 is in direct contact with the barrier forming region 36 (silicide layer 38), and forms a Schottky-junction portion SJ with the barrier forming region 36. A metal material constituting the first layer 43 is not particularly limited as long as the metal material can form a Schottky junction with the n-type second layer 16, and may be, for example, titanium (Ti), nickel (Ni), cobalt (Co), molybdenum (Mo), tungsten (W), etc. In the present preferred embodiment, the first layer 43 is a Co layer. Accordingly, in a manufacturing process described later, a silicide layer 38 made of CoSi₂ can be formed.

The second layer 44 is directly laminated on the first layer 43, and supplies the first layer 43 with voltage. A metal material constituting the second layer 44 may be, for example, Al (aluminum) or the like, or may be a polycrystal material such as polysilicon. A thickness of the second layer 44 may be, for example, larger than a thickness of the first layer 43.

The second conductive layer 41 has a quadrangular annular shape along the shape of the second opening 39 in a plan view as illustrated in FIG. 2. Referring to FIG. 3, the second conductive layer 41 may have a single-layer structure. The second conductive layer 41 is in direct contact with the cathode region 27, and forms an ohmic contact with the cathode region 27. A metal material constituting the second conductive layer 41 may be, for example, Al (aluminum), and may be a polycrystal material such as polysilicon.

A guard region 45 is further formed in a surface layer portion on the first principal surface 11 side of the semiconductor chip 4. The guard region 45 may be a p-type diffusion region selectively diffused in the n-type second layer 16 in the present preferred embodiment. The guard region 45 forms a pn-junction portion J2 with the second layer 16. A p-type impurity concentration of the guard region 45 is preferably higher than a p-type impurity concentration of the first layer 15. For example, the p-type impurity concentration of the guard region 45 may be 1×10¹⁶ cm⁻³ or more and 1×10¹⁷ cm⁻³ or less. In FIG. 3, to visually distinguish the concentration difference between the guard region 45 and the first layer 15, the guard region 45 is represented as a “p-type,” while the first layer 15 is represented as a “p⁻ type.” The “p⁻ type and the “p-type” are not conductivity types with impurity concentrations in a specific range, but are, for the sake of convenience, set to merely indicate that a concentration difference exists between the guard region 45 and the first layer 15.

The guard region 45 is connected to the first conductive layer 40 in the barrier forming region 36, and extends from the first principal surface 11 toward the second principal surface 12 in the thickness direction of the semiconductor chip 4. The guard region 45 is a region to be directly connected to the first conductive layer 40, and may, therefore, be rested as a p-type connection region.

Referring to FIG. 2, the guard region 45 is formed into an annular shape along the periphery of the first opening 37 in a plan view. The guard region 45 stretches from one side to the other of the inside and the outside of the first opening 37 with respect to an inner peripheral edge of the first shallow trench insulating structure 34. A portion of the guard region 45 overlaps the first shallow trench insulating structure 34 in a plan view. More specifically, the guard region 45 may integrally include an inner peripheral portion 46 exposed to the inside of the first opening 37 and an outer peripheral portion 47 formed outside the inner peripheral portion 46 and overlapping the first shallow trench insulating structure 34. The inner peripheral portion 46 may be formed into a closed annular shape in a plan view, exposed from the first opening 37 throughout the entire periphery of the inner peripheral edge of the first opening 37 and having a constant width. Similarly, the outer peripheral portion 47 may also be formed into a closed annular shape in a plan view, covered by the first shallow trench insulating structure 34 throughout the entire periphery of the inner peripheral edge of the first opening 37 and having a constant width. Comparing the widths of the inner peripheral portion 46 and the outer peripheral portion 47, the width W2 of the inner peripheral portion 46 may be narrower than the width W3 of the outer peripheral portion 47. Furthermore, the width W2 of the inner peripheral portion 46 may be narrower than a width W4 (width in a first direction X) of a portion (anode region 48) of the second layer 16 surrounded by the inner peripheral portion 46 and exposed from the barrier forming region 36. Accordingly, a range occupied by the guard region 45 (inner peripheral portion 46) in the barrier forming region 36 can be made smaller than the anode region 48, so that a current path of a forward current of the Schottky barrier diode 100 can be widely secured.

Referring to FIG. 3, a cross-sectional structure of the guard region 45 will be described. The guard region 45 is connected to the first conductive layer 40 in the barrier forming region 36, and when viewed in cross section, has a curved shape curved from the side surface 32 to the bottom surface 33 of the first shallow trench insulating structure 34. The guard region 45 may have a shape swelling from the side surface 32 and the bottom surface 33 of the first shallow trench insulating structure 34 in a direction intersecting the thickness direction of the semiconductor chip 4 and in the thickness direction of the semiconductor chip 4. Accordingly, the guard region 45 has a projecting portion 49 projecting to the second principal surface 12 side relative to the cathode region 27 and the first shallow trench insulating structure 34.

The guard region 45 is in direct contact with the side surface 32 and the bottom surface 33 of the first shallow trench insulating structure 34. The guard region 45 may be layered such that both of an inner side surface 50 in contact with the side surface 32 and the bottom surface 33 of the first shallow trench insulating structure 34 and an outer side surface 51 on the opposite side follow the side surface 32 and the bottom surface 33 of the first shallow trench insulating structure 34. In other words, the guard region 45 may be layered such that the outer side surface 51 of the guard region 45 becomes substantially parallel to the side surface 32 and the bottom surface 33. The guard region 45 has a depth larger than a depth of the cathode region 27 and a thickness of the first shallow trench insulating structure 34 with respect to the first principal surface 11.

The guard region 45 may integrally include a first portion 52 and a second portion 53 as a configuration distinguishable in a transverse direction along the first principal surface 11 of the semiconductor chip 4. The first portion 52 may be a portion of the guard region 45 extending along the side surface 32 of the first shallow trench insulating structure 34 from the first principal surface 11 toward the second principal surface 12 in the thickness direction of the semiconductor chip 4. The second portion 53 may be a portion of the guard region 45 which is formed along the bottom surface 33 of the first shallow trench insulating structure 34 from the first portion 52 in a direction intersecting the thickness direction of the semiconductor chip 4, and covers the bottom surface 33 of the first shallow trench insulating structure 34 from the second principal surface 12 side. Both of the first portion 52 and the second portion 53 are in direct contact with the side surface 32 and the bottom surface 33 of the first shallow trench insulating structure 34.

A guard contact region 54 is formed at the end portion on the first principal surface 11 side of the guard region 45. The guard contact region 54 is formed in a surface layer portion of the guard region 45 exposed from the first opening 37. The guard contact region 54 is formed into an annular shape along the inner peripheral edge of the first opening 37 as illustrated in FIG. 2. The guard contact region 54 forms an ohmic contact with the first conductive layer 40 (first layer 43). The conductivity type of the guard contact region 54 is the same as that of the guard region 45 and is a p-type. A p-type impurity concentration of the guard contact region 54 is preferably higher than a p-type impurity concentration of the guard region 45. For example, the p-type impurity concentration of the guard contact region 54 may be 1×10¹⁹ cm⁻³ or more and 1×10²¹ cm⁻³ or less.

In the Schottky barrier diode 100, a voltage is applied between the first conductive layer 40 and the second conductive layer 41 such that the first conductive layer 40 (anode conductive layer) becomes a positive side and the second conductive layer 41 (cathode conductive layer) becomes a negative side. Accordingly, a forward voltage is applied to the Schottky-junction portion SJ, and a forward current IF flows between the first conductive layer 40 and the second conductive layer 41.

On the other hand, as a voltage is applied such that the first conductive layer 40 (anode conductive layer) becomes a negative side and the second conductive layer 41 (cathode conductive layer) becomes a positive side, a reverse voltage is applied to the Schottky-junction portion SJ, and conduction through the Schottky-junction portion SJ is cut off. During this time, a reverse voltage is also applied to the pn-junction portion J2, such that a depletion layer can be spread from the pn-junction portion J2. Accordingly, the leak current when a reverse voltage is applied can be effectively prevented. As a result, a low forward voltage (VF) and a high switching speed as advantages of the Schottky barrier diode can be realized, and a reverse leak current can be prevented.

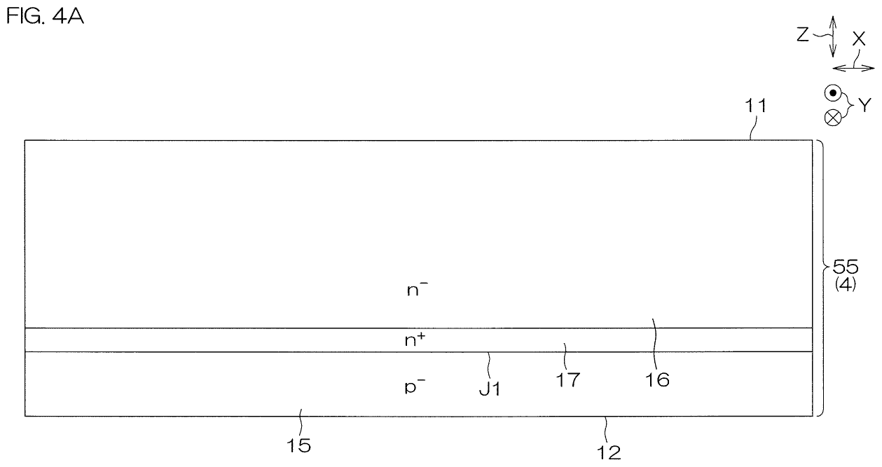

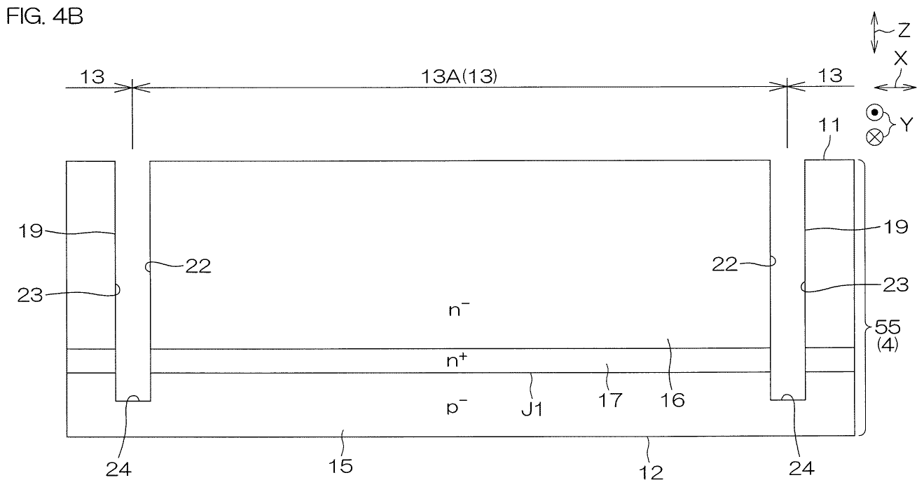

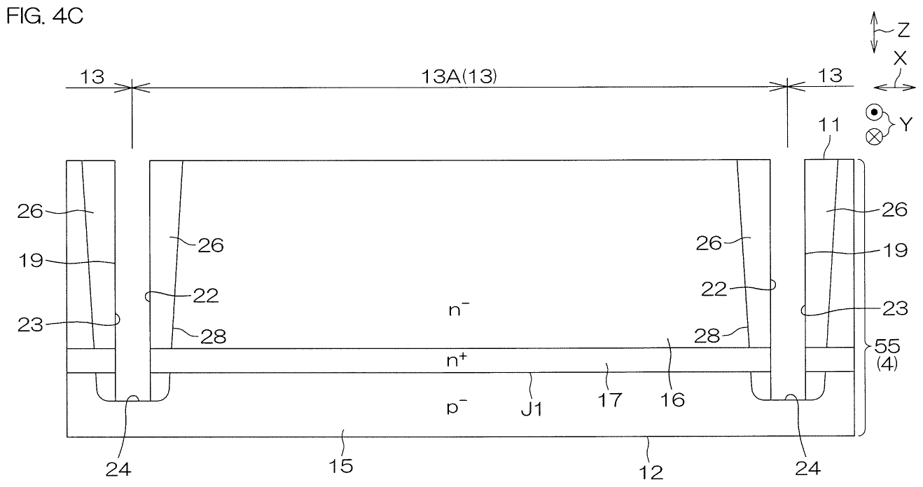

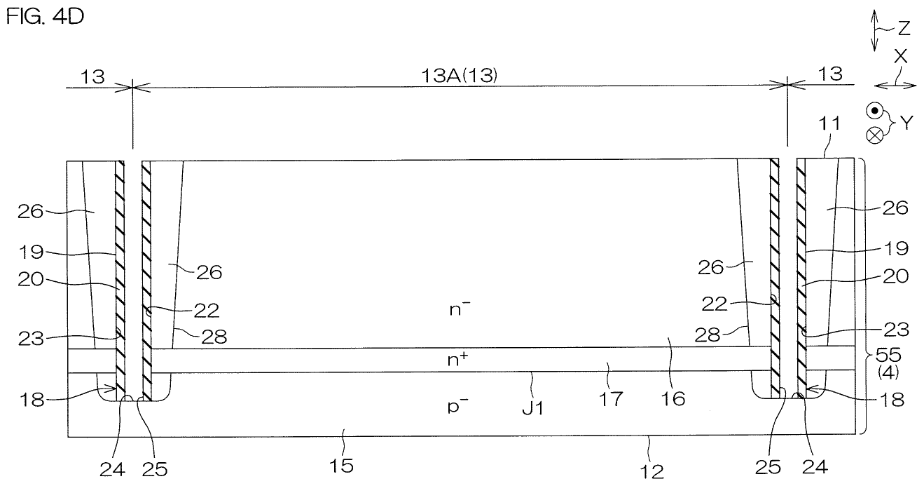

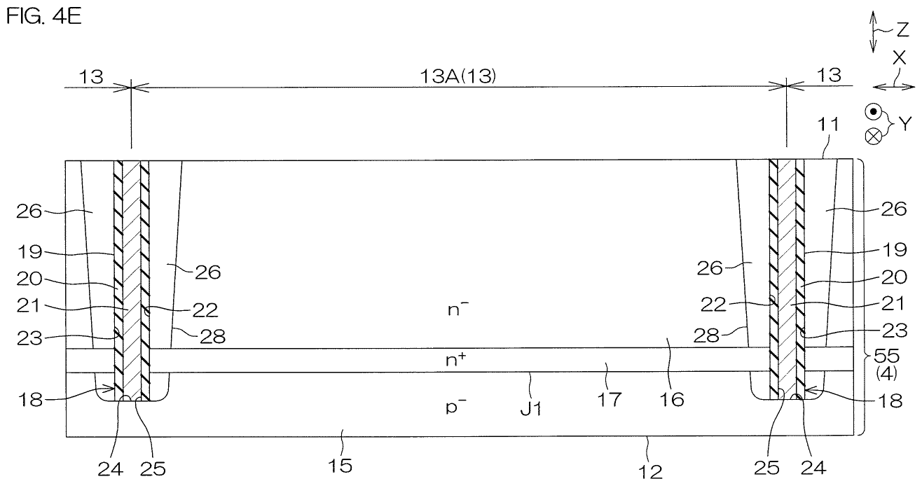

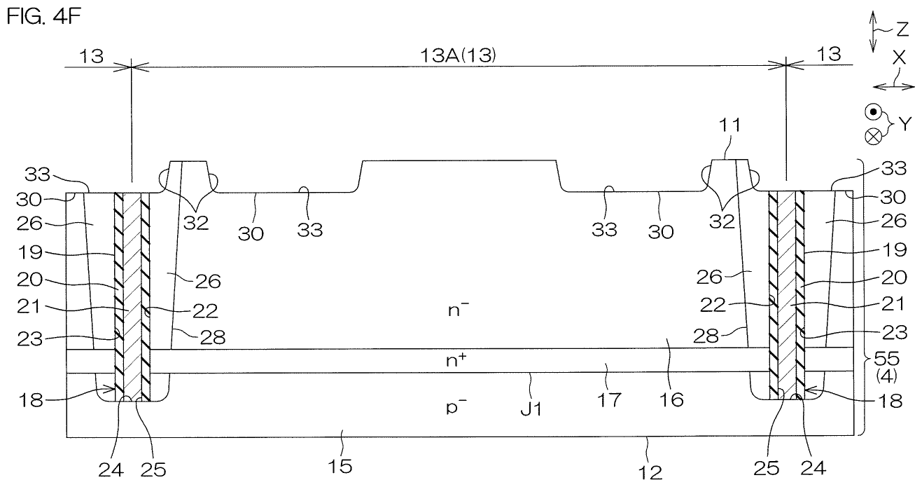

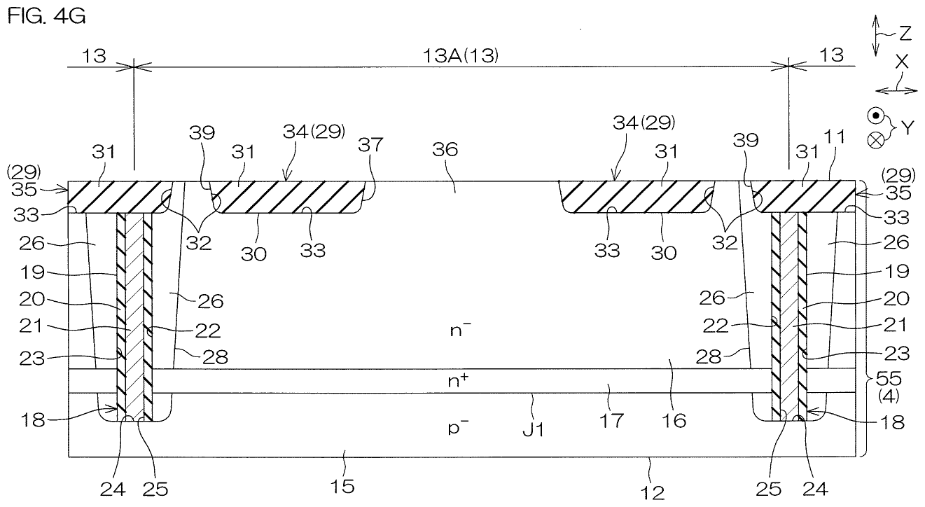

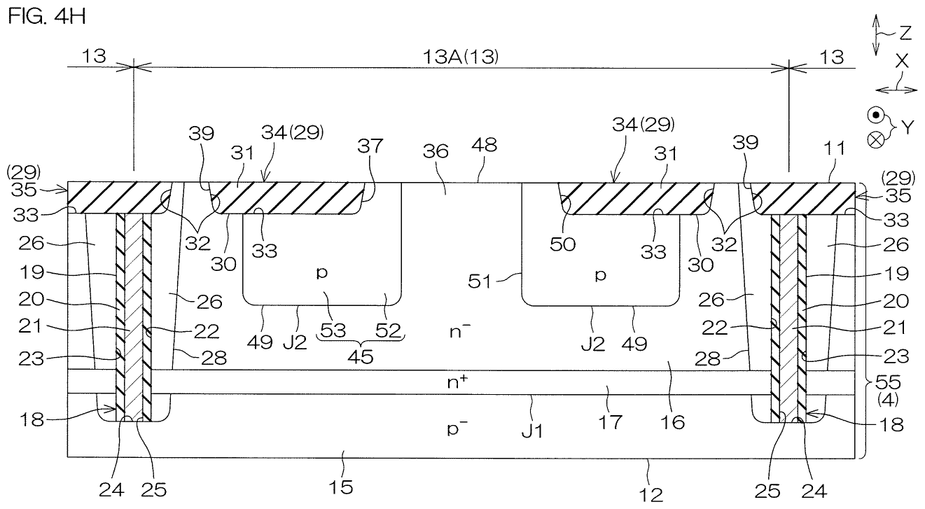

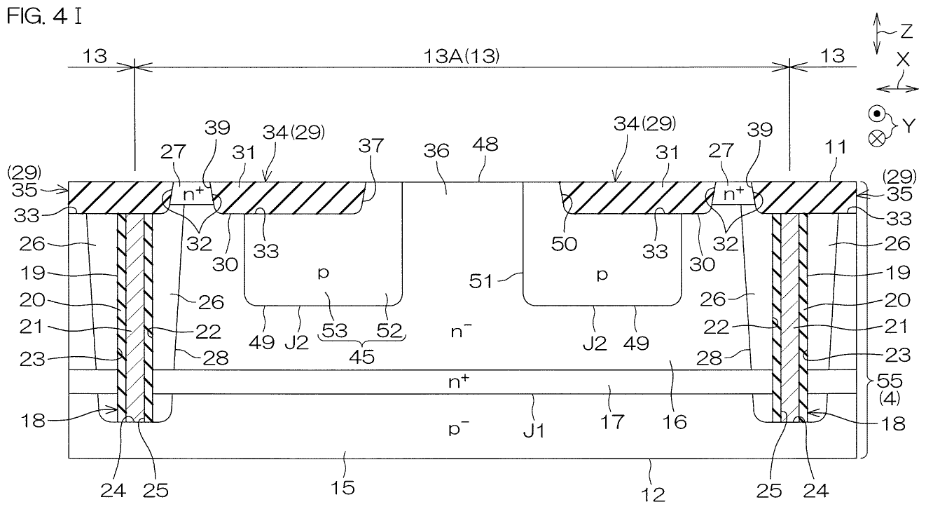

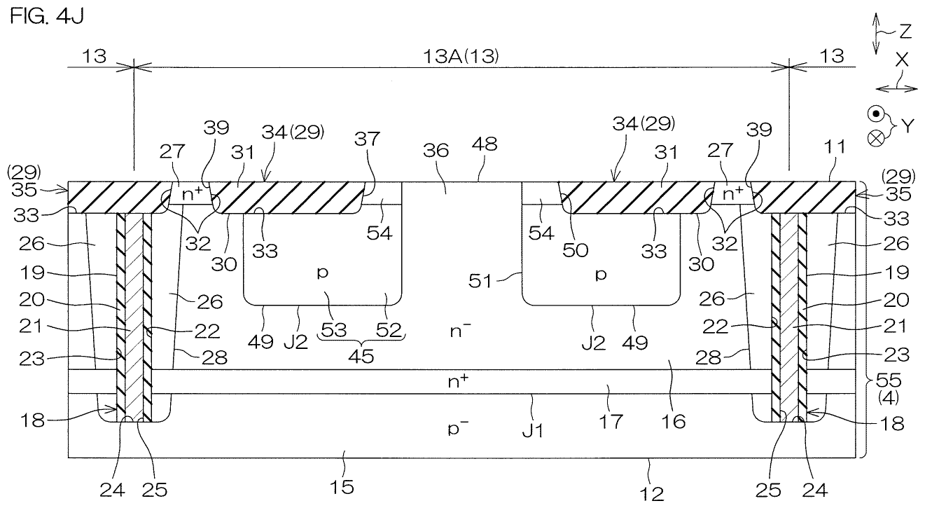

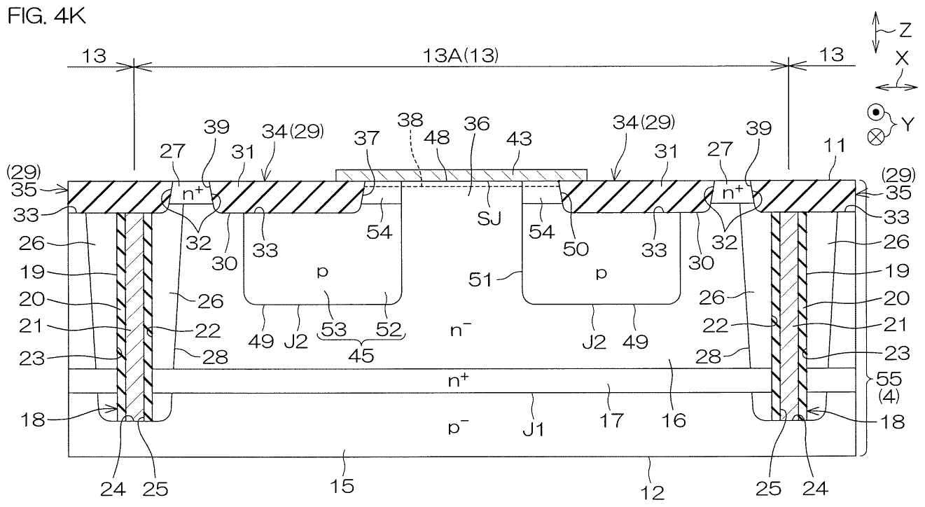

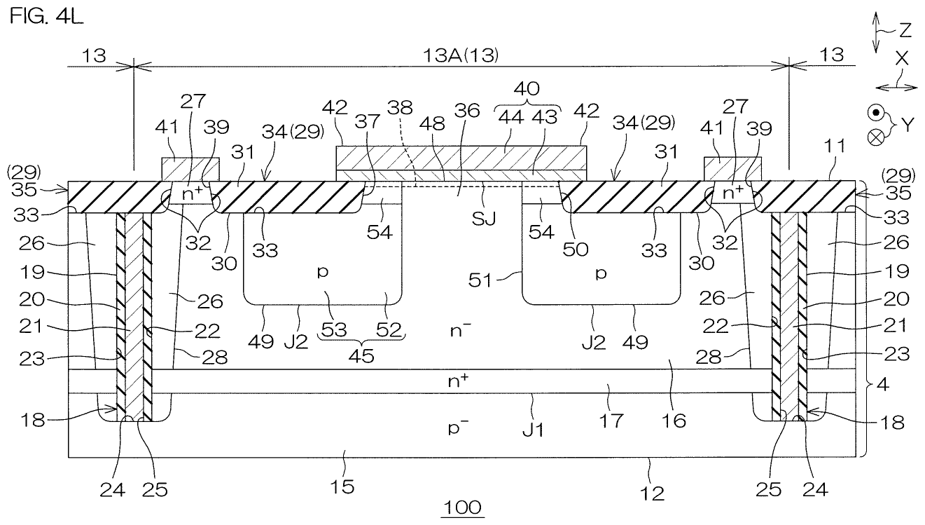

FIGS. 4A to 4L are drawings each illustrating a part of the manufacturing process of the Schottky barrier diode 100 illustrated in FIG. 3 in order of steps. Hereinafter, only steps relating to manufacturing of the Schottky barrier diode 100 are shown, and in parallel with or independently of the steps illustrated in FIGS. 4A to 4L, functional elements of the element regions 13 (the transistor region 13B and the resistor element region 13C, etc.) other than the diode region 13A may be formed.

To manufacture the Schottky barrier diode 100, with reference to FIG. 4A, a p-type semiconductor wafer 55 (first layer 15) as the base of the semiconductor chip 4 is prepared, and the embedded layer (third layer 17) and the second layer 16 are formed on the semiconductor wafer 55. For example, an n-type impurity (for example, phosphorus) is doped into a surface portion of the first layer 15. Next, by epitaxial growth of silicon while the n-type impurity is introduced, the second layer 16 is formed on the first layer 15. Then, the n-type impurity doped into the surface portion of the first layer 15 is diffused to both sides of the semiconductor wafer 55 in the thickness direction by annealing. Accordingly, the third layer 17 (embedded layer) is formed between the first layer 15 and the second layer 16. The obtained semiconductor wafer 55 has the above-described first principal surface 11 and second principal surface 12.

Next, with reference to FIG. 4B, a hard mask (for example, silicon oxide) is formed on the first principal surface 11 of the first layer 15, and the second layer 16 and the third layer 17 are selectively etched through the hard mask. Accordingly, the element isolation trench 19 is formed, and the diode region 13A is demarcated in the first layer 15.

Next, with reference to FIG. 4C, the n-type impurity is selectively doped into the inner wall (the inner peripheral wall 22, the outer peripheral wall 23, and the bottom wall 24) of the element isolation trench 19 and into the first principal surface 11 of the diode region 13A. The n-type impurity is doped at a tilt angle θ of 3° to 7° with respect to a normal n direction of the first principal surface 11. Accordingly, the n-type impurity can be efficiently doped into the inner peripheral wall 22 and the outer peripheral wall 23 of the element isolation trench 19. As the n-type impurity, phosphorus (P) or the like can be used. Accordingly, an impurity for the sinker layer 26 is introduced. For clarification, a region into which the impurity is doped is illustrated in FIG. 4C as the sinker layer 26.

Next, with reference to FIG. 4D, the element isolation insulating film 20 is formed on the inner wall (the inner peripheral wall 22, the outer peripheral wall 23, and the bottom wall 24) of the element isolation trench 19. The element isolation insulating film 20 is formed by, for example, thermal oxidation. Due to the heat at the time of formation of the element isolation insulating film 20, the n-type impurity in the inner peripheral wall 22 and the outer peripheral wall 23 of the element isolation trench 19 is diffused, and the sinker layer 26 is formed. Next, the portion of the element isolation insulating film 20 on the bottom wall 24 of the element isolation trench 19 is removed by etching. Accordingly, the contact hole 25 is formed.

Next, with reference to FIG. 4E, the element isolation electrode 21 is embedded in the element isolation trench 19. Next, with reference to FIG. 4F, the trench 30 of the shallow trench insulating structure 29 is formed in a surface layer portion of the first principal surface 11. Next, with reference to FIG. 4G, by backfilling the trench 30 with an insulating material, the embedded insulator 31 is formed.

Next, with reference to FIG. 4H, a p-type impurity for the guard region 45 is introduced into the second layer 16. For example, a mask (a hard mask, resist, or the like of SiO₂, etc.) having an opening corresponding to a region in which the guard region 45 should be formed is formed on the first principal surface 11. From the opening of the mask, a portion of the barrier forming region 36 and a portion of the first shallow trench insulating structure 34 are exposed. Next, through the mask opening, a p-type impurity is doped into the first principal surface 11. An acceleration voltage at the time of doping just needs to be set as appropriate such that the p-type impurity penetrates through the first shallow trench insulating structure 34 and reaches a lower side of the first shallow trench insulating structure 34. Accordingly, the p-type impurity for the guard region 45 is introduced into the surface layer portion of the second layer 16. For clarification, the region in which the p-type impurity is introduced is illustrated in FIG. 4H as the guard region 45.

Next, with reference to FIG. 4I, an n-type impurity for formation of the cathode region 27 is introduced into the second layer 16. For example, a mask (a hard mask, resist, or the like of SiO₂, etc.) having an opening corresponding to a region in which the cathode region 27 should be formed is formed on the first principal surface 11. From the opening of the mask, a portion of the second layer 16 is exposed. Next, the n-type impurity is doped into the first principal surface 11 through the mask opening. Accordingly, the n-type impurity for the cathode region 27 is introduced into the surface layer portion of the second layer 16. For clarification, the region in which the n-type impurity is introduced is illustrated in FIG. 4I as a cathode region 27.

Next, with reference to FIG. 4J, a p-type impurity for formation of the guard contact region 54 is introduced into the second layer 16. For example, a mask (a hard mask, resist, or the like of SiO₂, etc.) having an opening corresponding to a region in which the guard contact region 54 should be formed is formed on the first principal surface 11. From the opening of the mask, a portion of the guard region 45 is exposed. Next, through the mask opening, a p-type impurity is doped into the first principal surface 11. Accordingly, the p-type impurity for the guard contact region 54 is introduced into a surface layer portion of the second layer 16. Next, the n-type impurity and the p-type impurity previously introduced are diffused by heat treatment in the second layer 16. Accordingly, the guard region 45, the cathode region 27, and the guard contact region 54 are formed.

Next, with reference to FIG. 4K, the first layer 43 of the first conductive layer 40 is formed on the first principal surface 11 of the semiconductor wafer 55. The first layer 43 can be formed by a publicly known conductive layer forming method such as, for example, sputtering, vapor deposition, and plating. Then, by applying heat treatment, the silicide layer 38 is formed at a portion of the first principal surface 11 in contact with the first layer 43. In the present preferred embodiment, a Co layer is deposited as a material for the first layer 43, and by reacting the Co layer with the semiconductor wafer 55 (Si), the silicide layer 38 made of CoSi₂ can be formed.

After that, with reference to FIG. 4L, the second layer 44 of the first conductive layer 40 and the second conductive layer 41 are formed. The second layer 44 of the first conductive layer 40 and the second conductive layer 41 can be formed by a publicly known conductive layer forming method such as sputtering, vapor deposition, and plating. The Schottky barrier diode 100 described above is obtained through these steps.

A preferred embodiment of the present disclosure has been described above, and this disclosure may be carried out in other embodiments.

For example, in the description given above and the accompanying drawings, it is also possible that the n-type region is replaced with a p-type region, and the p-type region is replaced with an n-type region.

The preferred embodiment of the present disclosure so far described is an example in every respect and should not be understood in a limited manner. It is intended to include changes in every respect.

The features mentioned below are extractable from this description and from the drawings.

### [Appendix 1-1]

A semiconductor device comprising
a chip having a principal surface,
a pn-junction portion extending in a horizontal direction along the principal surface inside the chip,
a trench insulating structure formed in the principal surface such that the trench insulating structure penetrates through the pn-junction portion, and demarcating a diode region in the chip,
a barrier forming region formed in a surface layer portion of the principal surface in the diode region, and
a metal layer located on the principal surface such that the metal layer covers the barrier forming region in the diode region, and forming a Schottky-junction portion with the barrier forming region.

### [Appendix 1-2]

The semiconductor device according to Appendix 1-1, wherein the Schottky-junction portion is connected in reverse bias to the pn-junction portion.

### [Appendix 1-3]

The semiconductor device according to Appendix 1-1 or 1-2, wherein the trench insulating structure includes a trench formed in the principal surface, an insulation film covering a side wall of the trench such that the insulation film exposes a portion of the chip from a bottom wall of the trench, and an embedded electrode embedded in the trench with the insulation film in between such that the embedded electrode is electrically connected to the chip at the bottom wall of the trench.

### [Appendix 1-4]

The semiconductor device according to Appendix 1-3, wherein the embedded electrode is made of conductive polysilicon.

### [Appendix 1-5]

The semiconductor device according to any one of Appendixes 1-1 to 1-4, further comprising a cathode region formed in the surface layer portion of the principal surface and spaced from the barrier forming region in the diode region.

### [Appendix 1-6]

The semiconductor device according to Appendix 1-5, further comprising a shallow trench insulating structure formed between the barrier forming region and the cathode region in the principal surface.

### [Appendix 1-7]

The semiconductor device according to Appendix 1-6, wherein the metal layer has a portion drawn out from the barrier forming region onto the shallow trench insulating structure.

### [Appendix 1-8]

The semiconductor device according to Appendix 1-6 or 1-7, further comprising a guard region formed along the shallow trench insulating structure inside the chip, and having a conductivity type different from that of the cathode region.

### [Appendix 1-9]

The semiconductor device according to Appendix 1-8, wherein
the guard region has a swelling portion swelling to the barrier forming region side from a portion along the shallow trench insulating structure, and
the metal layer is electrically connected to the swelling portion of the guard region in the barrier forming region.

### [Appendix 1-10]

The semiconductor device according to Appendix 1-9, further comprising:
a high-concentration guard region formed in a surface layer portion of the swelling portion, and having a higher impurity concentration than the guard region, wherein
the metal layer is electrically connected to the high-concentration guard region in the barrier forming region.

### [Appendix 1-11]

The semiconductor device according to any one of Appendixes 1-8 to 1-10, wherein
the shallow trench insulating structure surrounds the barrier forming region in a plan view, and
the guard region surrounds the barrier forming region in a plan view.

### [Appendix 1-12]

The semiconductor device according to any one of Appendixes 1-5 to 1-11, further comprising a sinker region formed in the surface layer portion of the principal surface along the trench insulating structure in the diode region, and having the same conductivity type as that of the cathode region.

### [Appendix 1-13]

The semiconductor device according to Appendix 1-12, wherein the sinker region is connected to the cathode region.

### [Appendix 1-14]

The semiconductor device according to Appendix 1-12 or 1-13, wherein the sinker region is across the pn-junction portion in a thickness direction of the chip.

### [Appendix 1-15]

The semiconductor device according to any one of Appendixes 1-1 to 1-14, further comprising a silicide layer formed in a portion covered by the metal layer in the barrier forming region.

### [Appendix 1-16]

The semiconductor device according to Appendix 1-15, wherein
the metal layer includes at least one of a Ti layer, a Ni layer, a Co layer, a Mo layer, and a W layer, and
the silicide layer includes at least one of a TiSi layer, a TiSi₂ layer, a NiSi layer, a CoSi layer, a CoSi₂ layer, a MoSi₂ layer, and a WSi₂ layer.

### [Appendix 1-17]

The semiconductor device according to Appendix 1-16, wherein
the metal layer is formed by a Co layer, and
the silicide layer is formed by a CoSi₂ layer.

### [Appendix 1-18]

The semiconductor device according to any one of Appendixes 1-1 to 1-17, further comprising:
a plurality of device regions provided in the principal surface, wherein
the trench insulating structure electrically isolates the diode region from the plurality of device regions.

### [Appendix 1-19]

The semiconductor device according to Appendix 1-18, wherein the plurality of device regions respectively include functional devices each forming a portion of an integrated circuit.

### [Appendix 1-20]

The semiconductor device according to Appendix 1-19, wherein the Schottky-junction portion forms a portion of the integrated circuit.

What is claimed is:

1. A semiconductor device comprising:
a chip having a principal surface;
a pn-junction portion extending in a horizontal direction along the principal surface inside the chip;
a trench insulating structure formed in the principal surface such that the trench insulating structure penetrates through the pn-junction portion, and demarcating a diode region in the chip;
a barrier forming region formed in a surface layer portion of the principal surface in the diode region; and
a metal layer located on the principal surface such that the metal layer covers the barrier forming region in the diode region, and forming a Schottky-junction portion with the barrier forming region.

2. The semiconductor device according to claim 1, wherein the Schottky-junction portion is connected in reverse bias to the pn-junction portion.

3. The semiconductor device according to claim 1, wherein the trench insulating structure includes a trench formed in the principal surface, an insulation film covering a side wall of the trench such that the insulation film exposes a portion of the chip from a bottom wall of the trench, and an embedded electrode embedded in the trench with the insulation film in between such that the embedded electrode is electrically connected to the chip at the bottom wall of the trench.

4. The semiconductor device according to claim 3, wherein the embedded electrode is made of conductive polysilicon.

5. The semiconductor device according to claim 1, further comprising a cathode region formed in the surface layer portion of the principal surface and spaced from the barrier forming region in the diode region.

6. The semiconductor device according to claim 5, further comprising a shallow trench insulating structure formed between the barrier forming region and the cathode region in the principal surface.

7. The semiconductor device according to claim 6, wherein the metal layer has a portion drawn out from the barrier forming region onto the shallow trench insulating structure.

8. The semiconductor device according to claim 6, further comprising a guard region formed along the shallow trench insulating structure inside the chip, and having a conductivity type different from that of the cathode region.

9. The semiconductor device according to claim 8, wherein
the guard region has a swelling portion swelling to the barrier forming region side from a portion along the shallow trench insulating structure, and
the metal layer is electrically connected to the swelling portion of the guard region in the barrier forming region.

10. The semiconductor device according to claim 9, further comprising:
a high-concentration guard region formed in a surface layer portion of the swelling portion, and having a higher impurity concentration than the guard region, wherein
the metal layer is electrically connected to the high-concentration guard region in the barrier forming region.

11. The semiconductor device according to claim 8, wherein
the shallow trench insulating structure surrounds the barrier forming region in a plan view, and
the guard region surrounds the barrier forming region in a plan view.

12. The semiconductor device according to claim 5, further comprising a sinker region formed in the surface layer portion of the principal surface along the trench insulating structure in the diode region, and having the same conductivity type as that of the cathode region.

13. The semiconductor device according to claim 12, wherein the sinker region is connected to the cathode region.

14. The semiconductor device according to claim 12, wherein the sinker region is across the pn-junction portion in a thickness direction of the chip.

15. The semiconductor device according to claim 1, further comprising a silicide layer formed in a portion covered by the metal layer in the barrier forming region.

16. The semiconductor device according to claim 15, wherein
the metal layer includes at least one of a Ti layer, a Ni layer, a Co layer, a Mo layer, and a W layer, and
the silicide layer includes at least one of a TiSi layer, a TiSi₂ layer, a NiSi layer, a CoSi layer, a CoSi₂ layer, a MoSi₂ layer, and a WSi₂ layer.

17. The semiconductor device according to claim 16, wherein
the metal layer is formed by a Co layer, and
the silicide layer is formed by a CoSi₂ layer.

18. The semiconductor device according to claim 1, further comprising:
a plurality of device regions provided in the principal surface, wherein
the trench insulating structure electrically isolates the diode region from the plurality of device regions.

19. The semiconductor device according to claim 18, wherein the plurality of device regions respectively include functional devices each forming a portion of an integrated circuit.

20. The semiconductor device according to claim 19, wherein the Schottky-junction portion forms a portion of the integrated circuit.
